(19) United States
(12) Patent Application Publication
(10) Pub. No.: US 2026/0242208 A1
(43) Pub. Date: Aug. 20, 2026

(54) ANNULAR MICROELECTROMECHANICAL ANGULAR RATE SENSOR

(71) Applicant: Northrop Grumman Litef GmbH, Freiburg (DE)

(72) Inventor: Jan Daniel RENDE, Freisen (DE)

(21) Appl. No.: 18/872,360

(22) PCT Filed: May 16, 2023
(86) PCT No.: PCT/EP2023/063098

§ 371 Date: Dec. 6, 2024

(30) Foreign Application Priority Data
Jun. 8, 2022 (DE) 10 2022 114 407.0

(51) Int. Cl. B81B 3/00; G01C 19/00; G01C 19/5684

(52) U.S. Cl. CPC B81B 3/0086; G01C 19/005; G01C 19/5684; B81B 2201/0242; B81B 2203/0163; B81B 2203/0307; B81B 2203/04

(57) ABSTRACT

The invention relates to a microelectromechanical angular rate sensor (100) having a flexible ring structure (110) which forms a circle in an idle state and which is suitable for producing an excitation oscillation substantially parallel to the plane of the circle above a substrate, said excitation oscillation being superimposed with a detection oscillation produced by a Coriolis force during a rotation of the ring structure (110). The microelectromechanical angular rate sensor also has at least one coupling structure (120) which is connected to the ring structure (110) and is designed so as to be suitable for compensating for a quadrature error of the angular rate sensor (100) together with electrodes (130) which are fixed to the substrate.

The present invention relates to annular microelectromechanical angular rate sensors.

Annular microelectromechanical angular rate sensors operate according to the principle that a self-contained structure, which is typically designed as a circle or ring, is made to oscillate above a substrate parallel to the substrate plane. If the ring is rotated about an axis of rotation perpendicular to the substrate plane, the oscillation movement of the ring generates a Coriolis force on the individual mass points of the ring. This leads to the superimposition of a further oscillation, the amplitude of which depends on the angular rate of the rotation. As the oscillation direction of this detection oscillation is, in principle, predetermined by the position of the ring and the excitation oscillation, and the parameters of the excitation oscillation are also known, the detection oscillation can be read out in order to determine the angular rate.

In practice, plate electrodes placed along the circumference of the ring are often used to excite and read out the oscillations. However, this takes up a lot of space and does not meet all requirements for the angular rate sensor. Such plate electrodes can also be used to compensate for so-called quadrature errors, which often affect microelectromechanical sensors due to inevitably arising manufacturing tolerances.

However, the problem here is that electrode plates placed on the outside along the circumference of the ring are limited in terms of the electrode area. As a larger signal can be fed in or read out via a larger electrode area, the use of external electrode plates is disadvantageous. It is also not always possible to design the excitation and readout electrodes optimally with external electrode plates.

The object of the present invention is therefore to specify annular microelectromechanical angular rate sensors with a large electrode area, which have a compact design and allow compensation for quadrature errors without restricting the possibility of exciting the ring of the angular rate sensor or reading out oscillations.

This object is achieved by the subject matter of the claims.

A microelectromechanical angular rate sensor has a flexible ring structure, which forms a circle at rest and which is suitable for producing an excitation oscillation substantially parallel to the plane of the circle above a substrate, said excitation oscillation being superimposed with a detection oscillation generated by the Coriolis force during a rotation of the ring structure. Moreover, the angular rate sensor has at least one coupling structure, which is connected to the ring structure and is designed in such a way that it is, together with electrodes which are fixed to the substrate, suitable for compensating for a quadrature error of the angular rate sensor.

There is therefore no longer an attempt to compensate for quadrature errors via plate electrodes or similar, which act directly on the ring structure of the angular rate sensor. Instead, a coupling structure is connected to the ring structure to which compensation forces can be applied. The coupling structure then passes these compensation forces on to the ring structure and can thus compensate for quadrature errors. The specific design of the coupling structure is arbitrary, as long as the movements of the coupling structure caused by the compensation forces are transferred to the ring structure to a sufficient extent in order to be able to bring about a controllable and measurable influence on the movements of the ring structure through the strength of the compensation forces. Due to the small oscillation amplitudes that usually occur in microelectromechanical devices, it is typically sufficient for compensation to take place in a first approximation.

Moreover, the use of the coupling structure allows a freer placement and design of electrodes, which can provide an overall larger electrode area and enable an advantageous design of electrodes with different functions, such as excitation and readout electrodes.

In particular, the use of the coupling structure, especially when the spring stiffnesses of the various components of the angular rate sensor are designed appropriately, makes it possible to achieve that the size of the amplitude of the oscillations produced by the ring structure is greater than the size of the oscillation amplitudes of the coupling structure. This can also be used for an advantageous design of the electrodes, e.g., to achieve smaller gap distances or operation in the linear range.

The angular rate sensor can furthermore include first spring elements that connect the ring structure to the substrate, with the at least one coupling structure and the first spring elements acting on the same side of the ring structure. The ring structure is therefore connected to the substrate via spring elements. In this way, it is ensured that the ring structure can oscillate as freely as possible. All spring elements act on one side of the ring structure, i.e., either from the inside or from the outside, in order to ensure a force and torque-free coupling with respect to the substrate. The one or more coupling structures then act on the same side as the spring elements; if necessary, the coupling structures are also connected via the first spring elements. In this way, a relatively compact design of the angular rate sensor can be achieved, as important components of the angular rate sensor are arranged together. In particular, when the components are arranged inside the ring structure, the size of the angular rate sensor is determined by the size of the ring structure.

The angular rate sensor can have a plurality of the coupling structures that are evenly distributed along the circumferential direction of the ring structure. This improves the response behavior and the possibility to compensate for quadrature errors. Moreover, the coupling structures can be designed identically in construction due to the even distribution without causing uneven force distributions on the ring structure. This simplifies the manufacture of the angular rate sensor.

The electrodes for compensating for quadrature errors can be in electrical interaction with portions of the coupling structures that extend substantially in a radial direction of the ring structure. This makes it possible to rotate the coupling structures effectively in a circumferential direction of the ring structure, i.e., about an axis perpendicular to the substrate plane. This rotation is transferred to the ring structure due to the corresponding design of the coupling structures and leads to forces there that compensate for the quadrature errors.

The coupling structures can be designed as frames that are connected to the ring structure on a first side and to the substrate on a second opposite side. At least one portion of the electrodes which are fixed to the substrate is then formed within the frames. This achieves a compact design, as the electrodes used to control the angular rate sensor can be arranged entirely or partially within the coupling structures, so that no further space is required.

The electrodes for compensating for quadrature errors can be in electrical interaction with third sides of the frames, which extend substantially in a radial direction of the ring structure. The interaction described above for compensating for quadrature errors therefore takes place via appropriately aligned sides of the frame.

The first and second sides of the frames may be longer than the third sides of the frames. In a radial direction, the frames are thus relatively short, while, in a tangential direction, they are relatively long. The connection point between the frame and the ring structure, which is located on the corresponding first side, therefore has a relatively large distance in relation to the dimensions of the frame from the point at which the electrodes for compensating for quadrature errors are arranged. There is therefore a long lever arm between the point at which the force is generated to compensate for quadrature errors and the point at which it is transferred to the ring structure. As a result, relatively small excitations by means of the electrodes are sufficient to compensate for quadrature errors in order to bring about this compensation. This simplifies compensation, as charges or voltages on the electrodes can be omitted, the size of which can lead to other problems such as crosstalk or similar. Moreover, energy consumption is reduced.

The coupling structures can be designed in such a way that they, together with electrodes which are fixed to the substrate, are suitable for generating the excitation oscillation and/or measuring the detection oscillation. This means that not only the compensation for the quadrature errors but also the excitation and readout of the oscillations of the ring structure can be mediated via the coupling structures. This makes it possible to improve the operation of angular rate sensors. Drive, readout and/or error compensation can be mediated by the same or different coupling structures. The advantages mentioned above with regard to the electrode area and/or the electrode design then benefit all electrodes.

Furthermore, the angular rate sensor can include second spring elements that connect the coupling structures to the ring structure, whereas the second spring elements can be deformed in a radial direction of the ring structure in such a way that a radial deflection of the coupling structures leads to a greater radial deflection of the ring structure. The second spring elements fitted between the coupling structures and the ring structure therefore serve to amplify amplitudes. Comparatively small deflections of the coupling structures with short and large acceleration (comparable to a force impact) are absorbed by the second spring elements. The second spring elements are designed in such a way that this force impact with low amplitude leads to deformation in a radial direction, which causes a larger (and slower) deflection on the ring structure than was the case for the coupling structure. This has the advantage that large amplitudes can be applied to the ring structure without having to provide space for similarly large amplitudes on the coupling structures. As a result, the space requirement can be further reduced. Moreover, such amplitude amplification allows the coupling structures to be excited or read out with relatively small deflections. This means that the corresponding electrodes can be designed with a small gap width and operated in the linear range. At the same time, the oscillation amplitudes of the ring structure remain large, which is advantageous for precise angular rate determination.

The angular rate sensor can include third spring elements that connect the coupling structures to the substrate. This can improve the mobility of the coupling structures. This makes the transmission of forces between the coupling structures and the ring structure more flexible, as the coupling structures can also be moved as a whole and movements do not only have to result from the deformation of the coupling structures.

At least two of the coupling structures can be coupled to each other in such a way that their movements are coupled to each other. In particular, the coupling structures can be forced to move in the common mode or in push-pull mode through the coupling. This can improve the stability of the oscillations in the angular rate sensor and thus the readout accuracy.

The present invention will be described in an exemplary manner in the following text, with reference to the figures. The following description should not be understood as restrictive. The present invention is defined solely by the subject matter of the claims.

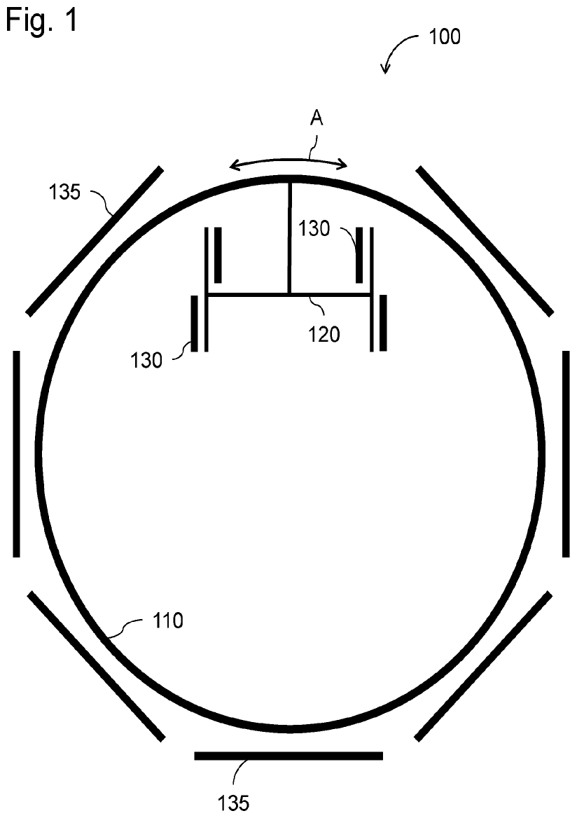

FIG. 1 shows a schematic representation of an annular micromechanical angular rate sensor;

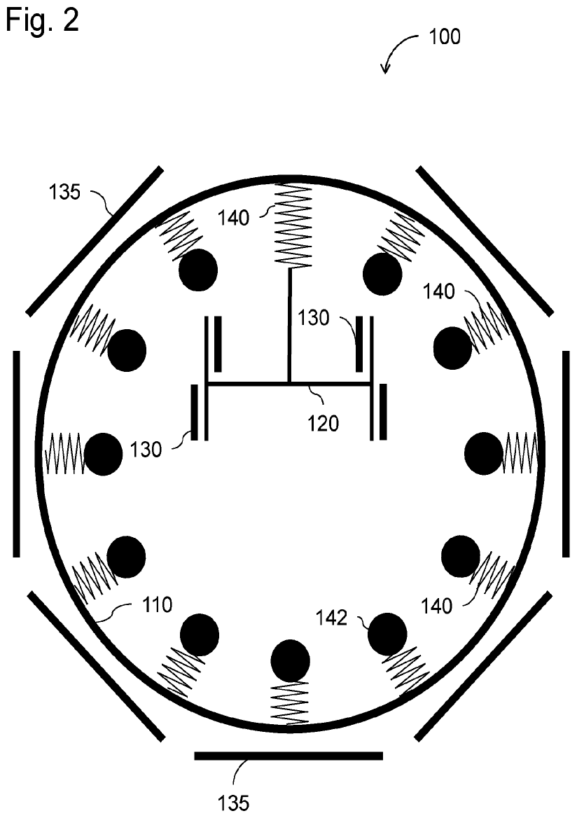

FIG. 2 shows another schematic representation of an annular micromechanical angular rate sensor;

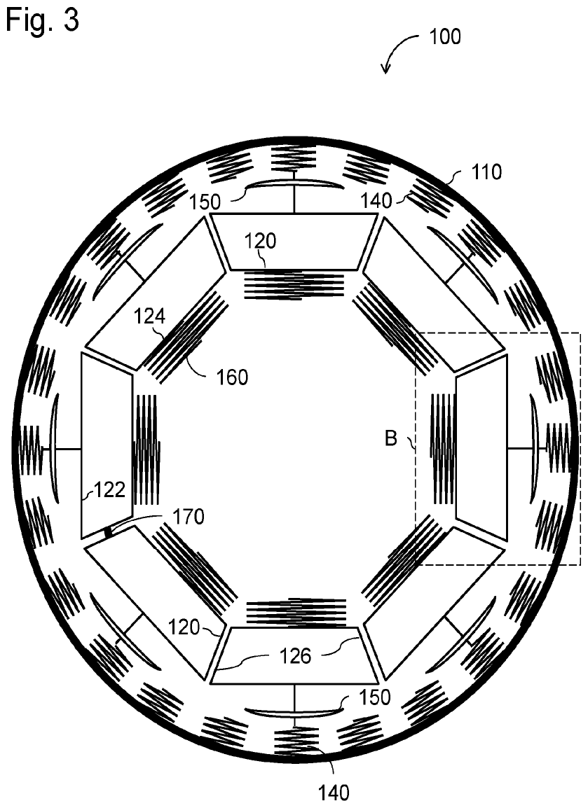

FIG. 3 shows another schematic representation of an annular micromechanical angular rate sensor;

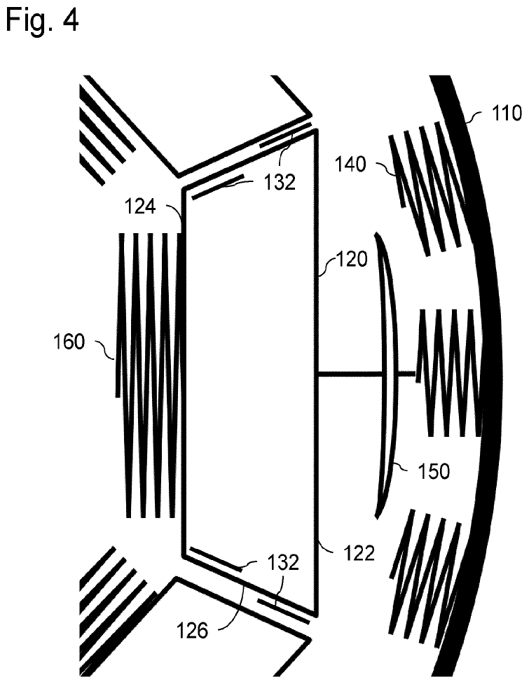

FIG. 4 shows a schematic representation of electrodes for compensating for quadrature errors of an annular angular rate sensor;

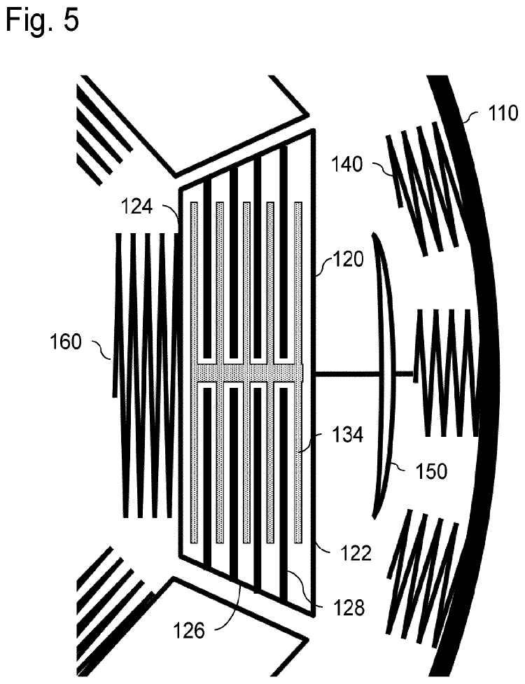

FIG. 5 shows a schematic representation of plate-shaped electrodes for exciting and/or reading out oscillations of an annular angular rate sensor;

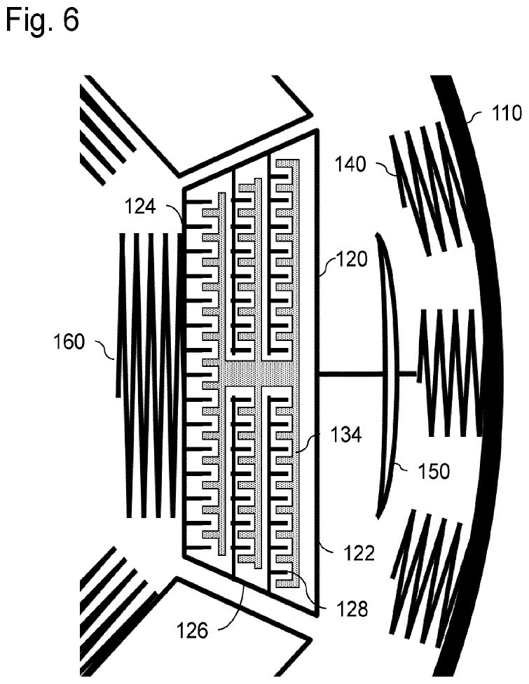

FIG. 6 shows a schematic representation of comb-shaped electrodes for exciting and/or reading out oscillations of an annular angular rate sensor; and

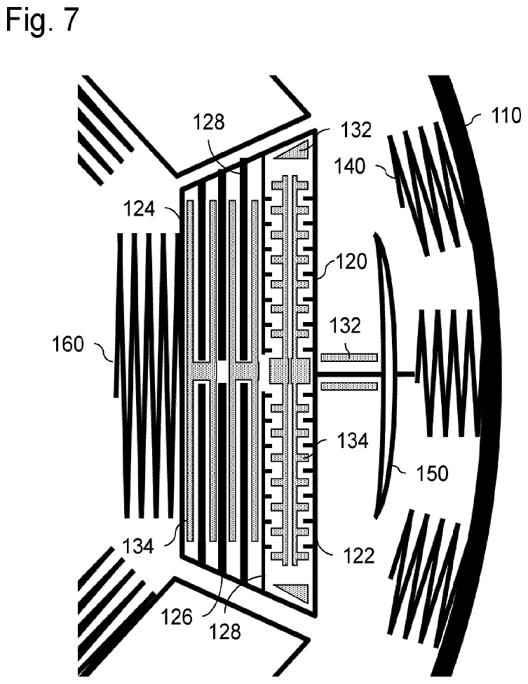

FIG. 7 shows a schematic representation of various electrodes for operating an annular angular rate sensor.

FIG. 1 shows a schematic representation of an annular microelectromechanical angular rate sensor 100. The angular rate sensor has a flexible ring structure 110, which forms a circle at rest and which is suitable for producing an excitation oscillation substantially parallel to the plane of the circle above a substrate, said excitation oscillation being superimposed with a detection oscillation generated by the Coriolis force during a rotation of the ring structure 110.

The ring structure 110, for example, can be a self-contained bending beam spring that is arranged above the substrate (not depicted) lying parallel to the image plane. This means that the ring structure 110 substantially consists of a bar the height of which (perpendicular to the image plane) is significantly higher than its width (in the image plane). As a result, the ring structure can be deformed parallel to the substrate, while it is rigid and inflexible with respect to deformations perpendicular to the substrate.

In order to measure angular rates, the ring structure 110 is set into a fundamental oscillation or excitation oscillation, which, for example, leads to elliptical deformation along a certain direction. If the angular rate sensor 100 rotates about an axis that is perpendicular to the substrate, a Coriolis force is generated on the mass points of the ring structure 110 due to the movements occurring as a result of the excitation oscillation, which leads to a change in the oscillation of the ring structure 110. This change, for example, can be regarded as the superposition of another oscillation over the excitation oscillation, whereas the oscillation direction of this detection oscillation differs from the oscillation direction of the excitation oscillation. In other words, the Coriolis force excites oscillation modes that differ from the oscillation mode(s) of the excitation oscillation. This change in the oscillation produced by the ring structure 110 can be measured in order to determine the angular rate of the rotation.

Although the ring structure 110 is shown as a circle at rest, this is not intended to exclude any shapes that are suitable for detecting Coriolis forces/angular rates in the same way. For example, the ring structure 110 can also deviate from the circular shape at rest and, for example, be formed as a deformed circle, as a polygon with or without rounded edges or the like. All these variations are to be understood as falling under the term “circle”.

Moreover, the angular rate sensor 100 has at least one coupling structure 120 which is connected to the ring structure 110 and is designed in such a way that it is, together with electrodes 130 which are fixed to the substrate, suitable for compensating for a quadrature error of the angular rate sensor 100. Such quadrature errors are almost inevitably present due to manufacturing tolerances occurring during the manufacture of microelectromechanical components. In particular, due to the use of etching processes during manufacture, components with the same design can be dimensioned slightly differently. For example, the thickness of the ring structure 110 can vary along the circumferential direction. This leads to different spring hardnesses and thus to an undesirable, different response behavior to force effects. In order to be able to operate the angular rate sensor 100 as if these deviations from the ideal behavior were not present, the deviations must be compensated for by applying additional force.

This is usually attempted with plate electrodes 135, which are arranged on the outside or inside of the ring structure 110 and interact electrically with it. However, the problem here is that compensation forces cannot be generated in a sufficiently targeted manner due to the flat design of the plate electrodes 135. Moreover, it is not possible to apply forces in any direction to ring structure 110 via the plate electrodes 135, and the area available for the plate electrodes 135 is limited by the circumference of the ring structure 110.

In order to avoid these problems, the angular rate sensor 100 has at least one, preferably more, coupling structures 120. The coupling structure 120 is subjected to forces via electrodes 130 connected to the substrate. The coupling structure 120 is designed in such a way that precise transmission of these compensation forces to the ring structure 110 is made possible. The specific design of the coupling structure 120 and the electrodes 130 is arbitrary as long as this function can be achieved.

In particular, the coupling structure 120 must make it possible to apply tangential forces to the ring structure 110, which are symbolized by the double arrow A in FIG. 1. This is achieved, for example, by allowing the coupling structure 120 to rotate about an axis perpendicular to the substrate, whereby a tensile force acts in a tangential direction on connection points between the coupling device 120 and the ring structure 110.

As depicted in FIG. 1, the coupling structure 120 is preferably connected to the ring structure 110 at exactly one point for this purpose. This allows to precisely determine the point of application of the compensation force. However, the coupling structure 120 can also be connected to the ring structure 110 at several points, whereby, for example, dimensional stability can be achieved in the connection area.

As depicted in FIG. 1, the electrodes 130 can be arranged on different parts of the coupling structure 120 to compensate for quadrature errors. This increases the effective area available for the electrode areas. It is also possible to achieve designs of the electrodes 130 that deviate from the plate structure and are precisely matched to the function of the electrodes 130. This applies not only to the electrodes 130 for compensating for quadrature errors, but to all electrodes acting on the coupling structure 120, as will be described in detail further below.

In this process, the electrodes for compensating for quadrature errors can preferably be arranged on parts of the coupling structure 120 that extend substantially in the radial direction of the ring structure 110. Components running substantially radially are to be understood here as components that have a larger radial than tangential direction vector, such as the external sides of the coupling structure 120 depicted in FIG. 1. Then the electrodes 130, for example, can be designed in a simple manner as plate electrodes which generate forces perpendicular thereto on the substantially radially running parts of the coupling structure 120, i.e., substantially tangentially running forces which are suited to tangentially displace or twist the coupling structure 120.

In addition to tangential forces, radial forces can also be applied to the ring structure 110 via the coupling structure 120 when an appropriate shape and appropriate electrodes 130 are used. In contrast to the conventionally used plate electrodes 135, the coupling structure 120 thus allows compensation forces to be generated in all directions and also to be applied precisely to the ring structure 110. This effectively reduces quadrature errors, especially when several coupling structures 120 are used. A larger electrode area can also be achieved in this way by dividing the electrode area.

As depicted in FIG. 2, the angular rate sensor 100 can include first spring elements 140, which connect the ring structure 110 to the substrate via anchor structures 142. The first spring elements 140 serve to hold the ring structure 110 above the substrate and, at the same time, enable the oscillations necessary for operation of the angular rate sensor 100. The design of the first spring elements 140 is at the discretion of a person skilled in the art. This is symbolized in FIG. 2 by the use of a zigzag line as the general pictogram for “spring”. The decisive factor in this context is not the shape of the first spring elements 140, but rather that the at least one coupling structure 120 and all of the first spring elements 140 act on the same side of the ring structure 110. In FIG. 2, this is the inside of the ring structure 110. However, the first spring elements 140 and the at least one coupling structure 120 could also be located outside the ring structure 110.

By connecting the first spring elements 140 and the coupling structure(s) 120 to the same side of the ring structure 110, a compact design of the angular rate sensor 100 can be achieved. In particular, the side of the ring structure 110 without spring elements 140 and coupling structure(s) 120 is free for the arrangement of various other components of the angular rate sensor 100.

FIG. 3 shows another schematic representation of an exemplary embodiment of an angular rate sensor 100. In addition to the components described above, the angular rate sensor 100 has a plurality of coupling structures 120 that are evenly distributed along the circumferential direction of the ring structure 110. Moreover, the example in FIG. 3 depicts second spring elements 150, which connect the coupling structures 120 to the ring structure 110, and third spring elements 160, which connect the coupling structures 120 to the substrate. Anchor structures that connect the first and third spring elements 140, 160 to the substrate are not depicted for the sake of clarity. The second and third spring elements 150, 160 are each optional.

The use of a plurality of coupling structures 120 distributed along the circumference of the ring structure 110 allows sufficient compensation forces to be applied to the ring structure 110 at each point in order to compensate for quadrature errors. The optional even distribution has the further advantage that the results of the force effect on the ring structure can be more easily estimated or predicted, since an even distribution is easier to deal with theoretically. Moreover, equally designed coupling structures 120 guarantee the desired rotational symmetry of the angular rate sensor 100 in this way. Since it is easier to manufacture equally shaped coupling structures 120 than differently shaped ones (e.g., due to the easier manufacturability of equally dimensioned structures during an etching process), the even distribution of the coupling structures 120 also simplifies the manufacturing process of the angular rate sensor 100.

As depicted in FIG. 3, the coupling structures 120 can be designed as frames that are connected to the ring structure 110 on a first side 122 and to the substrate on a second opposite side 124. This allows that at least one portion of the electrodes 130 which are fixed to the substrate and which can interact with the coupling structures 120, is formed within the frames. In this way, the structures for exciting/detecting movements of the coupling structures 120 can be arranged in a compact, space-saving manner within the angular rate sensor 100. Moreover, the use of frames increases the area that can interact with electrodes compared to the area of circumferential sections of the ring structure 110 that interact with simple electrode plates 135.

As further exemplified in FIG. 3, the first sides 122 and the second sides 124 of the frames may be longer than third sides 126 of the frames that extend substantially in a radial direction of the ring structure 110. The frames thus have the shape of an elongated rectangle or trapezoid, which is connected to the ring structure 110 or the substrate on the longitudinal sides. On one hand, this is a space-saving design of the coupling structures 120.

On the other hand, this shape of the coupling structures 120 allows electrodes 132 to be placed in electrical interaction with the third sides 126 to compensate for quadrature errors. This is exemplified in FIG. 4, which shows an enlargement of the area marked with B in FIG. 3. The compensation for quadrature errors can be effectively brought about by this structure, since the comparatively long first sides 122 and second sides 124 provide a large lever arm between the point of application of the force caused by the electrodes 132 and the connection between the coupling device 120 and the ring structure 110. A comparatively small force transmission at the third sides 126 thus leads to an increased force on the ring structure 110 due to the lever arm, which can be used to compensate for quadrature errors. The ratio of the lengths of the first side 122 to the third sides 126 can be between 3:1 and 10:1, e.g., 5:1.

In addition to or instead of the electrodes 132 to compensate for quadrature errors, electrodes 134 which are fixed to the substrate can also be formed in or on the frames that constitute the coupling structures 120, via which the excitation oscillation of the ring structure 110 is generated or via which the detection oscillation is measured. Examples of such electrode structures are depicted in FIGS. 5 to 7 with reference to area B of FIG. 3. In all these figures, it is clear that both the electrode area and the design options for the individual electrodes have been greatly improved compared to the use of external plate electrodes.

FIG. 5 depicts electrodes 134 constructed as plates for driving/reading out the oscillations of the ring structure 110, which alternate with electrode plates 128 that are connected to the frame. The electrodes 134 and the electrodes 128 form plate capacitors via which a force can be applied to the frame in a radial direction, or with which such a force can be detected. The structure depicted in FIG. 5 can be used in a plurality of coupling devices 120. It can be used in individual coupling devices 120 solely for the drive and in others solely for detection. However, the same structure can also be used in temporal multiplexing for both tasks.

In FIG. 6, the electrodes 134 for driving/reading out the oscillations of the ring structure are designed as comb electrodes that engage in comb electrodes 128 that are connected to the frame. Radial movements can also be excited/detected with such a design.

FIG. 7 shows a combination of the various electrode shapes depicted in FIGS. 4 to 6. In addition to electrodes 134 designed as plates and combs for driving/readout operations and their counter electrodes 128 connected to the frame, there are also electrodes 132 for compensating for quadrature errors, which can interact with the frame and with the connection of the frame to the ring structure 110.

FIGS. 4 to 7 show that the frame structure makes it possible to achieve considerable space savings in addition to full functionality. When considered in context of FIG. 3 and the arrangement of the first spring elements 140 depicted therein, this results in an extremely compact structure of the angular rate sensor 100.

As discussed above, radial forces, in particular, can be applied to the ring structure 110 via the coupling structures 120. The amplitude of the deformation of the ring structure 110 caused by these forces can be increased by appropriately designed second spring elements 150. For this purpose, the second spring elements 150 must have a low spring constant with regard to radial deflections. A spring that is soft in a radial direction leads to large deformation of the spring in the event of a force impact with a small amplitude, which is then transferred to the ring structure 110. In this way, a suitable choice of connection between the coupling structure 120 and the ring structure 110 can achieve amplitude amplification, which can be advantageous for applying drive or compensation forces to ring structure 110.

As depicted in FIG. 3, the second spring elements 150, for example, can be designed as double-folded springs. Moreover, these can interact with the first spring elements 140. However, the second spring elements 150 can also be connected directly to the ring structure 110. Instead of the double-folded springs depicted, any other spring design can also be used which is sufficiently soft in a radial direction to achieve the aforementioned purpose of amplitude amplification.

The third spring elements 160 that are also depicted in FIG. 3 serve to increase the mobility of the coupling structures 120. This simplifies the transmission of forces from the coupling structures 120 to the ring structure 110. The third spring elements 160 can be designed according to technical requirements.

As indicated by the line 170 in FIG. 3, at least two of the coupling structures 120 are coupled to each other in such a way that their movements are coupled to each other. The movement of the one coupling structure 120 then influences the movement of the other coupling structure 120 and vice versa. In particular, it can be advantageous for adjacent coupling structures 120 to move in the common mode or in push-pull mode in order to cause and/or stabilize a desired oscillation mode of the ring structure 110. The coupling of the coupling structures 120 to one another can take any form that allows this objective to be achieved.

As is clear from the above description, the angular rate sensor 100 is characterized by the coupling structure 120, which is designed in such a way that it is, together with electrodes 130 which are fixed to the substrate, suitable for compensating for a quadrature error of the angular rate sensor 100. In this way, particularly reliable annular angular rate sensors 100 can be provided.

1-11. (canceled)

12. A microelectromechanical angular rate sensor, comprising:
a flexible ring structure which forms a circle at rest and which is suitable for producing an excitation oscillation substantially parallel to the plane of the circle above a substrate, said excitation oscillation being superimposed with a detection oscillation generated by the Coriolis force during a rotation of the ring structure;
at least one coupling structure which is connected to the ring structure and is designed in such a way that it is, together with electrodes which are fixed to the substrate, suitable for compensating for a quadrature error of the angular rate sensor; and
first spring elements which act on the ring structure at their first ends and are connected to the substrate at their second ends via anchor structures; wherein
the at least one coupling structure and the first spring elements act on the same side of the ring structure.

13. The angular rate sensor according to claim 12, wherein
the angular rate sensor has a plurality of coupling structures that are evenly distributed along the circumferential direction of the ring structure.

14. The angular rate sensor according to claim 12, wherein
the electrodes for compensating for quadrature errors are in electrical interaction with portions of the coupling structures that extend substantially in a radial direction of the ring structure.

15. The angular rate sensor according to claim 12, wherein
the coupling structures are designed as frames that are connected to the ring structure on a first side and to the substrate on a second opposite side; and
at least one portion of the electrodes which are fixed to the substrate is formed within the frames.

16. The angular rate sensor according to claim 15, wherein
the electrodes for compensating for quadrature errors are in electrical interaction with third sides of the frames, which extend substantially in a radial direction of the ring structure.

17. The angular rate sensor according to claim 16, wherein
the first and second sides of the frames are longer than the third sides of the frames.

18. The angular rate sensor according to claim 12, wherein
the coupling structures are designed in such a way that they, together with electrodes which are fixed to the substrate, are suitable for generating the excitation oscillation and/or measuring the detection oscillation.

19. The angular rate sensor according to claim 12, further comprising:
second spring elements which connect the coupling structures to the ring structure; wherein
the second spring elements are deformable in a radial direction of the ring structure in such a way that a radial deflection of the coupling structures leads to a greater radial deflection of the ring structure.

20. The angular rate sensor according to claim 12, further comprising:
third spring elements which connect the coupling structures to the substrate.

21. The angular rate sensor according to claim 12, wherein
the angular rate sensor has at least two coupling structures that are coupled to each other through a connection in such a way that their movements are coupled to each other.

22. A microelectromechanical angular rate sensor, comprising:
a flexible ring structure which forms a circle at rest and which is suitable for producing an excitation oscillation substantially parallel to the plane of the circle above a substrate, said excitation oscillation being superimposed with a detection oscillation generated by the Coriolis force during a rotation of the ring structure; and
at least one coupling structure which is connected to the ring structure and is designed in such a way that it is, together with electrodes which are fixed to the substrate, suitable for compensating for a quadrature error of the angular rate sensor, wherein
the coupling structures are designed as frames that are connected to the ring structure on a first side and to the substrate on a second opposite side;
at least one portion of the electrodes which are fixed to the substrate is formed within the frames; and
the electrodes for compensating for quadrature errors are in electrical interaction with third sides of the frames, which extend substantially in a radial direction of the ring structure.

23. The angular rate sensor according to claim 12, wherein
the first and second sides of the frames are longer than the third sides of the frames.

24. A microelectromechanical angular rate sensor, comprising:
a flexible ring structure which forms a circle at rest and which is suitable for producing an excitation oscillation substantially parallel to the plane of the circle above a substrate, said excitation oscillation being superimposed with a detection oscillation generated by the Coriolis force during a rotation of the ring structure;
at least one coupling structure which is connected to the ring structure and is designed in such a way that it is, together with electrodes which are fixed to the substrate, suitable for compensating for a quadrature error of the angular rate sensor; and
second spring elements which connect the coupling structures to the ring structure; wherein
the second spring elements are deformable in a radial direction of the ring structure in such a way that a radial deflection of the coupling structures leads to a greater radial deflection of the ring structure.
